(19) United States
(12) Patent Application Publication
(10) Pub. No.: US 2007/0298710 A1
(43) Pub. Date: Dec. 27, 2007

(54) Audio interfaces

(76) Inventor: Trevor J. Sams, Totnes (GB)

Correspondence Address: WELSH & KATZ, LTD, 120 S RIVERSIDE PLAZA, 22ND FLOOR, CHICAGO, IL, 60606, US

(21) Appl. No.: 11/474,186

(22) Filed: Jun. 23, 2006

(51) Int. Cl. H04H 7/00; H04B 1/18; H05K 11/02

(52) U.S. Cl. 455/3.06; 455/152.1; 455/345

(57) ABSTRACT

A device (5) for connecting an audio device to a radio frequency receiver (1) comprises an audio signal input (9), an encoder connected to receive an audio signal from the audio signal input and operable to generate an encoded radio frequency signal from a received audio signal, and an output for direct connection to an antenna connection of an radio frequency receiver.

The present application relates to audio interfaces, and in particular to audio interfaces for use with automotive audio systems.

### BACKGROUND OF THE PRESENT INVENTION

With the continued increase in the popularity of personal audio players (such as MP3 players) many users would like to be able to connect a personal audio player to a vehicle audio system. Existing high quality devices tend to be expensive, and complex to connect to the vehicle audio system. Cheaper connecting systems are also available, but these tend to be of low quality, since they make use of an audio cassette pickup device, or use a short range, low power, FM (frequency modulated) radio transmission to which the user must tune the radio of their audio system in order to listen to audio tracks from their personal audio player. The short range FM radio transmitter has several disadvantages, not least of which is that interference free FM frequencies are few and far between, and the locations of free frequencies varies across territories and countries.

Accordingly, it is desirable to provide an audio interface for an automotive audio system which can overcome the disadvantages of the existing systems, and can provide high quality, easy to fit devices, at reasonable cost.

### SUMMARY OF THE PRESENT INVENTION

According to the present invention there is provided a device for connecting an audio device to a radio frequency receiver, the device comprising an audio signal input, an encoder connected to receive an audio signal from the audio signal input and operable to generate an encoded radio frequency signal from a received audio signal, and an output for direct connection to an antenna connection of an radio frequency receiver.

In one embodiment, the encoder is operable to produce a frequency modulated radio frequency signal. Alternatively, the encoder is operable to produce a digitally encoded signal representative of the received audio signal. Alternatively, the encoder is operable to produce a encoded signal compatible with Digital Audio Broadcasting standards. Alternatively, the encoder is operable to produce a encoded signal compatible with Digital Satellite Radio standards.

In one embodiment, the audio signal input comprises an audio jack socket. In another embodiment, the audio signal input comprises an optical receiver. In another embodiment, the audio signal input comprises a radio receiver.

According to another aspect of the present invention, there is provided, an audio system comprising a radio receiver having an antenna connection, and such a connection device, connected directly to the antenna connection of the radio receiver.

### BRIEF DESCRIPTION OF THE DRAWINGS

FIG. 1 is a schematic block diagram illustrating an automotive audio system and a device embodying the present invention; and

FIG. 2 is a schematic block diagram illustrating a device embodying the present invention in more detail.

### DETAILED DESCRIPTION OF THE PREFERRED EMBODIMENTS OF THE INVENTION

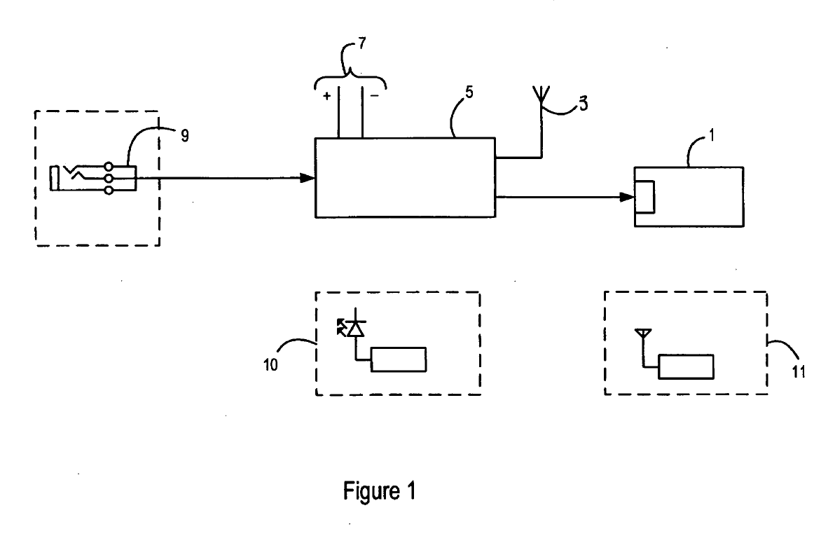

FIG. 1 illustrates an automotive audio system 1 to which a connection devices embodying the present invention is connected to enable connection of a personal audio device to the automotive audio system 1. The connection device 5 is connected between the audio system 1 and a radio antenna 3. The connection device 5 is connected to a power supply 7, preferably the vehicle power supply, and is also connected to an audio interface 9. In one example embodiment, the audio interface 9 comprises a 3.5 mm jack socket for receiving a 3.5 mm standard jack plug from a personal audio device. The audio interfaces could be replaced by an optical interface, illustrated at 10, or a wireless radio interface, shown at 11, which uses a suitable wireless networking or communication standard, such as, but not limited to Bluetooth™ or IEEE 802.1.1. The connection device 5 receives an audio signal from the personal audio device through the audio or other interface 9, 10, 11 and supplies that audio signal as a frequency modulated radio frequency signal to the audio system 1 via the antenna connection of the audio system.

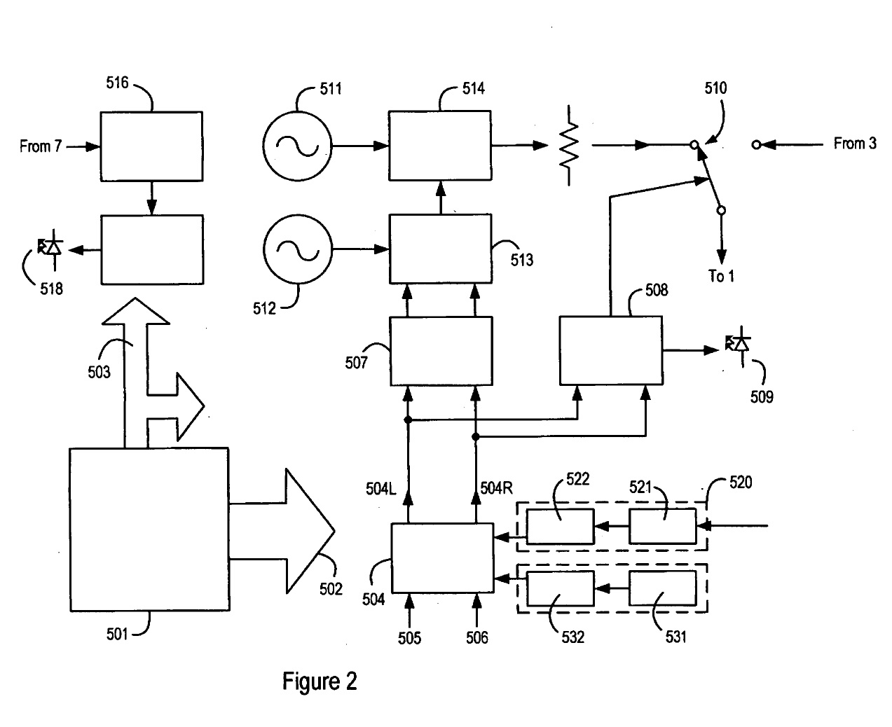

FIG. 2 illustrates a connection device 5 embodying the present invention in more detail. The device 5 includes a micro controller 1 and control logic 502 and 503 for controlling the overall function of the connection device S. The device 5 includes an audio multiplexer 504 which is connected to receive audio inputs 505 and 506 from personal audio devices. For example, the personal audio device could be an MP3 player, compact disc (CD) player, or any other device capable of producing an audio output signal. In addition, or alternatively, the audio multiplexer 504 can receive audio signal inputs from wireless input devices 520 and 530. A radio frequency wireless input device 520 includes a wireless radio receiver 521 and a signal conditioning circuit 522. An optical input device 530 is also illustrated, and this includes an optical input circuit 531 and a signal conditioning circuit 530.

An audio multiplexer 504 generates left and right audio signals 504L and 504R for supply to the remainder of the circuit. An audio pre-emphasis circuit 507 serves to amplify the left and right audio signals supplied by the audio multiplexer 504, and supplies an amplified signal to the FM circuit of the device 5. In addition, the left and right audio signals 504L and 504R are supplied to an audio detection circuit 508 which serves to provide an audio indicator signal to an audio indicator device, such as an LED (which could be integral with the 3.5 mm jack socket), 509. When the audio detector circuit 508 detects that an audio signal is being supplied from the audio multiplexer, the audio indicator 509 is caused to illuminate. In addition, the audio detector controls a switch device 510 which switches the output of the connector device 5 between the vehicle antenna and an output of the connector device circuitry, as will be explained in more detail below. In this way, the connection device 5 is able to isolate its output from the vehicle antenna, which prevents unwanted radio frequency transmission from that antenna.

The frequency modulation (FM) circuit of the device 5 will now be explained. The stereo multiplexer 513 receives a reference signal, for example, but not limited to, 76 KHz, from a reference oscillator 512. The stereo multiplexer 513 uses the reference signal to generate a single multiplexed output and supplies this output to a frequency synthesiser 514. In one particular example, the frequency synthesiser 514 receives a reference frequency signal from a reference oscillator 511 and produces a frequency modulated radio frequency signal in the usual manner which transmits the audio signals as an FM RF signal. Alternatively, the connection device 5 can employ other modulation methods, and/or provide a digital RF output in line with Digital Audio Broadcasting (DAB) or Digital Satellite Radio standards. It will be readily appreciated that the FM modulator could be replaced with any suitable RF encoder for providing an appropriate encoded signal to the RF receiver.

An RF attenuator may be provided in order to reduce the level of the RF signal to an appropriate level for supply to the antenna input of the vehicle audio system. The output signal can be such that the user tunes the radio receiver of the car audio system to a particular frequency, set by the reference oscillator 511 for reception of the audio signals.

Another preferred embodiment could include an adjustable RF pre-amplifier to take account of insertion losses such as when a heated rear screen element is used for an antenna

A device embodying the present invention has several advantages over the previously considered devices, and in particular, the isolation of the vehicle antenna 3 from the radio receiver 1, means that a high quality FM signal can be received by the radio receiver without unwanted FM transmissions being generated by the connector device 5. Furthermore, the device embodying the present invention is easily fitted to existing automotive audio systems and is easily hidden from view when connected to such systems. Furthermore, in some jurisdictions, FM transmitters which radiate within the Broadcast Radio spectrum are illegal. A device embodying the present invention does not radiate an FM broadcast, since the RF signal is conducted to the antenna port of the audio system, and so will be legal to operate anywhere.

1. A device for connecting an audio device to a radio frequency receiver, the device comprising:
an audio signal input;
an encoder connected to receive an audio signal from the audio signal input and operable to generate an encoded radio frequency signal from a received audio signal; and
an output for direct connection to an antenna connection of an radio frequency receiver.

2. A device as claimed in claim 1, wherein the encoder is operable to produce a frequency modulated radio frequency signal.

3. A device as claimed in claim 1, wherein the encoder is operable to produce a digitally encoded signal representative of the received audio signal.

4. A device as claimed in claim 1, wherein the encoder is operable to produce a encoded signal compatible with Digital Audio Broadcasting standards.

5. A device as claimed in claim 1, wherein the encoder is operable to produce a encoded signal compatible with Digital Satellite Radio standards.

6. A device as claimed in claim 1, wherein the audio signal input comprises an audio jack socket.

7. A device as claimed in claim 1, wherein the audio signal input comprises an optical receiver.

8. A device as claimed in claim 1, wherein the audio signal input comprises a radio receiver.

9. An audio system comprising a radio receiver having an antenna connection, and a device as claimed in any one of the previous claims, connected directly to the antenna connection of the radio receiver.
